(19) United States
(12) Patent Application Publication
(10) Pub. No.: US 2026/0099454 A1
(43) Pub. Date: Apr. 9, 2026

(54) OPTICAL MEMORY MODULE, CACHE MANAGER FOR AN OPTICAL MEMORY MODULE

(71) Applicant: Celestial AI Inc., Santa Clara, CA (US)

(72) Inventors: Philip Winterbottom, San Jose, CA (US); Martinus Bos, San Jose, CA (US); Trung Diep, San Jose, CA (US); David Lazovsky, Los Gatos, CA (US); Francisco Jose Maia da Silva, Porto (PT)

(73) Assignee: Celestial AI Inc., Santa Clara, CA (US)

(21) Appl. No.: 19/417,306

(22) Filed: Dec. 11, 2025

Related U.S. Application Data
(63) Continuation of application No. PCT/US2024/052556, filed on Oct. 23, 2024.
(60) Provisional application No. 63/592,517, filed on Oct. 23, 2023.

(51) Int. Cl. G06F 13/40; G06F 13/16; G06F 13/42

(52) U.S. Cl. CPC G06F 13/4072; G06F 13/1668; G06F 13/4221; G06F 2213/0026

(57) ABSTRACT

Systems and methods that include an optical memory module and cache manager for an optical memory module are disclosed. In an example, a memory module includes a photonic integrated circuit (PIC), an electric integrated circuit (EIC) stacked on the PIC and having a first memory interface and a second memory interface, photonic transceivers optically coupled to the PIC and electrically coupled to the EIC, first memory electrically coupled to the first memory interface of the EIC, second memory electrically coupled to the second memory interface of the EIC, the EIC including a cache manager between the first memory interface and the second memory interface, and a memory controller between the first memory and the photonic transceivers, and the PIC, EIC, photonic transceivers, first memory, and second memory are co-packaged.

### CROSS-REFERENCES

This is a U.S. continuation application under 35 U.S.C. 111(a) claiming priority under 35 U.S.C. 120 to international patent application PCT/US2024/052556, filed Oct. 23, 2024, which is incorporated by reference herein, and which is entitled entitled to the benefit of provisional U.S. patent application Ser. No. 63/592,517, filed Oct. 23, 2023, which is incorporated by reference herein.

### BACKGROUND

Demands for memory in artificial intelligence (AI) computing, such as machine learning (ML) and deep learning (DL), are increasing faster than they can be met by increases in available capacity offerings. This rising demand and the growing complexity of AI models drive the need to move large volumes of data between compute and/or memory nodes in a data center. In many conventional distributed systems, data movement leads to significant power consumption, poor performance, and excessive latency. Thus, multi-node computing systems that can process and transmit data between nodes quickly and efficiently may be advantageous for the implementation of AI computing.

### BRIEF DESCRIPTION OF THE DRAWINGS

FIG. 1A is a perspective view of an example of a circuit package that includes an EIC that is stacked on a PIC to produce a multiport network switch.

FIG. 1B is a side view of the circuit package from FIG. 1A that includes the EIC and the PIC, and in which the PIC is mounted on a substrate.

FIG. 2A is a side view of an example photonic transceiver of a multiport network switch relative to an EIC and a PIC in which a portion of the photonic transceiver is embodied in the EIC and a portion of the photonic transceiver is embodied in the PIC.

FIG. 2B is an expanded side view of the photonic transceiver from FIG. 2A.

FIG. 2C shows a view of the bottom major surface of the EIC, including the driver interface and the amplifier interface exposed at the bottom major surface of the EIC.

FIG. 3 depicts an example of a memory module that includes an EIC stacked on a PIC, a first memory unit, and a second memory unit, in which at least one photonic transceiver is formed between the EIC and the PIC.

FIG. 4 is an expanded view of an example of the cache manager from FIG. 3.

FIG. 5 is a flowchart showing an example operation of a memory module.

FIG. 6 is a flowchart showing another example operation of a memory module.

FIG. 7 depicts another example of a memory module that includes an EIC stacked on a PIC, a first memory unit, and a second memory unit, in which at least one photonic transceiver is formed between the EIC and the PIC.

FIG. 8 is a process flow diagram of an example of a method for operating a memory module.

FIG. 9A is a top view of an example of a memory module that includes an EIC stacked on a PIC.

FIG. 9B is a side view of the memory unit shown in FIG. 9A at cross section AA.

FIG. 10 is a top view of a memory module similar to the top view of FIG. 9A, which illustrates signal paths between the EIC, the PIC, the DDR units, and the HBM units.

FIG. 11 is a top view of an example EIC that shows various functional blocks that may be fabricated within the EIC.

FIG. 12 is a side cutaway view of a memory module that includes a substrate, a PIC, and an EIC stacked on the PIC, a DDR unit, an HBM unit, and an external optical interface.

FIG. 13 depicts a memory module that is optically connected to a GPU.

FIG. 14 depicts an example of an optical memory appliance that includes sixteen memory modules that are interconnected to each other by a crossbar.

Throughout the description, similar reference numbers may be used to identify similar elements.

### DETAILED DESCRIPTION

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment”, “an embodiment”, or similar language means that a particular feature, structure, or characteristic described in connection with the indicated embodiment is included in at least one embodiment of the present invention.

Thus, the phrases “in one embodiment”, “in an embodiment”, and similar language throughout this specification may, but do not necessarily, all refer to the same embodiment.

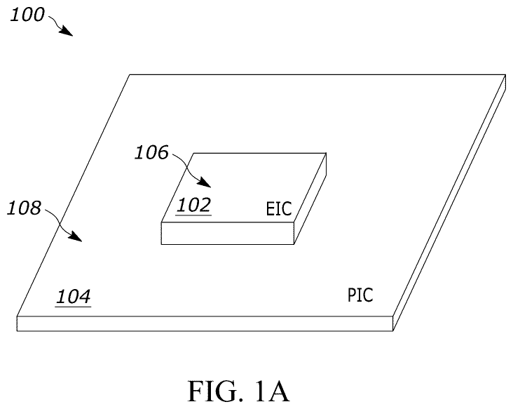

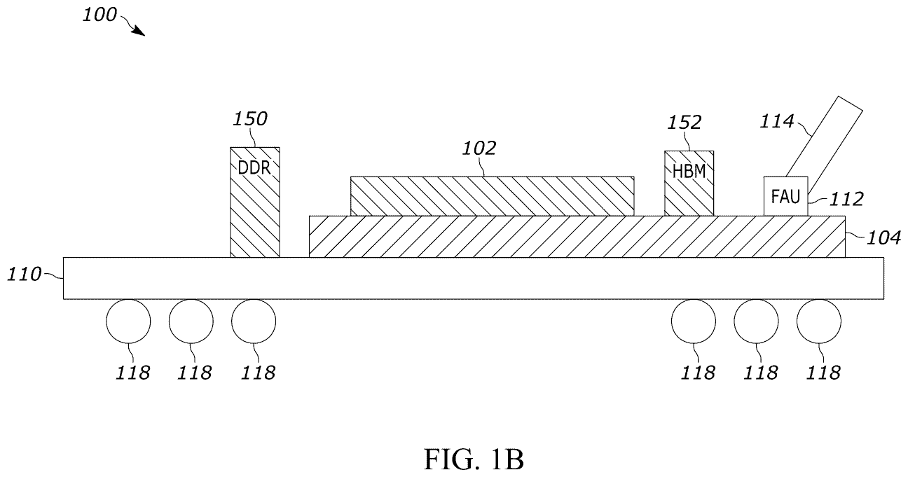

FIG. 1A is a perspective view of an example of a circuit package 100 that includes an EIC 102 that is stacked on a PIC 104 to produce a memory module that includes multiple photonic transceivers (not shown). In the example, both the EIC and the PIC are planar structures that have two major surfaces, referred to herein as a top major surface and a bottom major surface. In the perspective view of FIG. 1A, the top major surfaces 106 and 108 of both the EIC and the PIC are visible and the bottom major surface of the EIC is directly adjacent to, and parallel to the plane of, the top major surface of the PIC. It should be noted that the EIC and the PIC are not to scale and their sizes relative to each other may be different from that which is shown in FIG. 1A.

Additionally, the PIC may be attached to a planar substrate that includes electrical connections to the PIC and to the EIC. In an example, the EIC and PIC are physically and electrically connected to each other by electrical interconnects, e.g., solder bumps, and the distance between the bottom major surface of the EIC and the top major surface of the PIC is less than 2 mm and in many cases less than 50 microns.

FIG. 1B is a side view of the circuit package 100 from FIG. 1A that includes the EIC 102 and the PIC 104, and in which the PIC is mounted on a substrate 110. FIG. 1B also depicts a first memory unit 150, a second memory unit 152, optical elements, including an external optical interface 112 such as fiber array unit (FAU) on the PIC and external waveguides 114 (e.g., optical fibers) connected to the FAUs. Again, it should be noted that the elements depicted in FIG. 1B may not be to scale. In the example of FIGS. 1A and 1B, the EIC and the PIC are formed in separate semiconductor chips, typically silicon chips, although the use of other semiconductor materials is possible. In the example of FIG. 1B, the PIC is attached directly to the substrate and the substrate includes solder bumps 118 for subsequent mounting to, for example, a printed circuit board (PCB). In the example of FIG. 1B, the FAU that connects the PIC to the external waveguides (e.g., optical fibers) is positioned on top of and optically connected to the PIC although other means of connecting optical waveguides to the PIC are possible. Optionally, the circuit package 100 shown in FIGS. 1A and 1B may further include other elements that are attached on to the PIC.

In the example of FIG. 1B, the first memory unit 150 is DDR memory and the second memory unit 152 is HBM memory although other types of memory are possible. In the example of FIG. 1B, the first memory unit (e.g., DDR) is physically attached directly to the substrate 110 and the second memory unit (e.g., HBM) is physically attached directly to the PIC 104. The first and second memory units are described in more detail below.

In an example, an FAU is a device used in optical communication systems that combines or separates optical signals from multiple fibers into a single optical signal or multiple optical signals, respectively. The FAU can be used for a variety of applications, such as wavelength division multiplexing (WDM), parallel optical interconnects, and optical sensing. There are two main types of fiber array units that can be used: linear and circular. Linear FAUs combine or separate optical signals along a straight line, while circular fiber array units combine or separate optical signals in a circular configuration. Both types of FAUs are typically made from a precision-molded optical plastic or ceramic material and can have anywhere from a few to hundreds of fibers arranged in a specific pattern. The choice of FAU depends on the specific requirements of an application, such as the number of fibers, the arrangement of the fibers, the wavelength of light being used, and the coupling efficiency desired.

In an example, the EIC 102 includes high-speed integrated circuits configured to support the management of data between the first and second memory units 150 and 152, respectively, and the photonic transceivers. The EIC may be an application specific integrated circuit (ASIC), a field programmable gate array (FPGA), or a System on Chip (SoC) that is designed and fabricated using state of the art CMOS nodes. The EIC may include circuits for serialization/deserialization, clock and data recovery, modulator drivers, and amplifiers that implement the photonic transceivers and circuits that implement the switching circuitry.

A waveguide may be a structure that guides and/or confines light waves to facilitate the propagation of the light along a desired path and to a desired location. For example, a waveguide may be an optical fiber, a planar waveguide, a glass-etched waveguide, a photonic crystal waveguide, a free-space waveguide, any other suitable structure for directing optical signals, and combinations thereof. In some embodiments, one or more internal waveguides are formed in the PIC 104. In some embodiments, one or more external waveguides are implemented external to the PIC, such as the optical fibers 114 or a ribbon comprising multiple optical fibers.

The PIC 104 may include one or more internal waveguides that are optically coupled to the external optical interface 112 of the memory module. For example, as will be discussed below in more detail, one or more of the optical interfaces may be optically coupled to another optical port on another computing device. In some examples, an internal waveguide of the PIC is implemented (e.g., formed) in the PIC to connect photonic elements internally within the PIC. In another example, one or more external optical interfaces of the PIC may be optically coupled to an optical interface of another computing device located in a separate circuit package or separate chip to form inter-chip connections. In some embodiments, an external waveguide is implemented in connection with the PIC in order to connect photonic interfaces across multiple chips. For example, the external optical interfaces of the PIC may be connected via optical fibers across multiple chips. In some embodiments, an external waveguide (e.g., optical fiber) connects directly to photonic ports of respective computing devices across multiple chips. In some embodiments, an external waveguide is implemented in connection with one or more internal waveguides formed in the PIC of one or more of the chips. For example, one or more internal waveguides may internally connect one or more of the photonic ports to one or more additional optical components located at another portion of the circuit package (e.g., another portion of the PIC) to facilitate coupling with the external waveguides. For example, the internal waveguides within the PIC may connect to one or more optical coupling structures including FAUs located over grating couplers (GCs), or edge couplers. In some embodiments, one or more FAUs are implemented to facilitate coupling the external waveguides to the internal waveguides of the PIC to facilitate chip-to-chip interconnection to another circuit package to both transmit and receive optical signals. In some embodiments, one or more FAUs are implemented to supply optical power from an external laser light source to the PIC to drive the photonics (e.g., provide one or more optical carrier signals) in the PIC.

In an example, the EIC 102 and the PIC 104 may be manufactured using standard wafer fabrication processes, including, e.g., photolithographic patterning, etching, ion implantation, etc. Further, in some embodiments, heterogeneous material platforms and integration processes are used. For example, various active photonic components, such as laser light sources and optical modulators and/or photodetectors used in the photonic transceivers, may be implemented using group III-V semiconductor components.

As will be appreciated by those of ordinary skill in the art, the depicted structure of the circuit package 100 is merely one of several possible ways to assemble and package the various components. In some examples, some or all of the EIC 102 is disposed on the substrate 110. In some examples, it is also possible to create the EIC and the PIC 104 in different layers of a single semiconductor chip. In some examples, the photonic circuit layer includes or is made of multiple PICs. Multiple layers of PICs, or a multi-layer PIC may help to reduce waveguide crossings.

Moreover, the structure depicted in FIGS. 1A and 1B may be modified to include multiple EICs connected to a single PIC. For example, multiple EICs may be connected to each other via photonic channels in the PIC. Additionally, although the DDR 150 is attached to the substrate and the HBM 152 is attached to the PIC, other configurations are possible, including both the DDR and the HBM being attached to the PIC.

In an example, a light source, or light sources, is/are optically coupled to the circuit package 100, e.g., a memory module. The light source or light sources may include laser light sources that are implemented either in the circuit package or externally. When implemented externally, a connection to the circuit package may be made optically using a grating coupler in the PIC 104 underneath the FAU 112 and/or using an edge coupler. In some embodiments, lasers are implemented in the circuit package by using an interposer containing several lasers that can be co-packaged and edge-coupled with the PIC. In some embodiments, the lasers are integrated directly into the PIC using heterogenous or homogenous integration. Homogenous integration allows lasers to be directly implemented in the silicon substrate in which the waveguides of the PIC are formed, and allows for lasers of different materials, such as indium phosphide (InP), and architectures such as, quantum dot lasers. Heterogenous assembly of lasers on the PIC allows for group III-V semiconductors or other materials to be precision-attached onto the PIC and optically coupled to a waveguide implemented on the PIC.

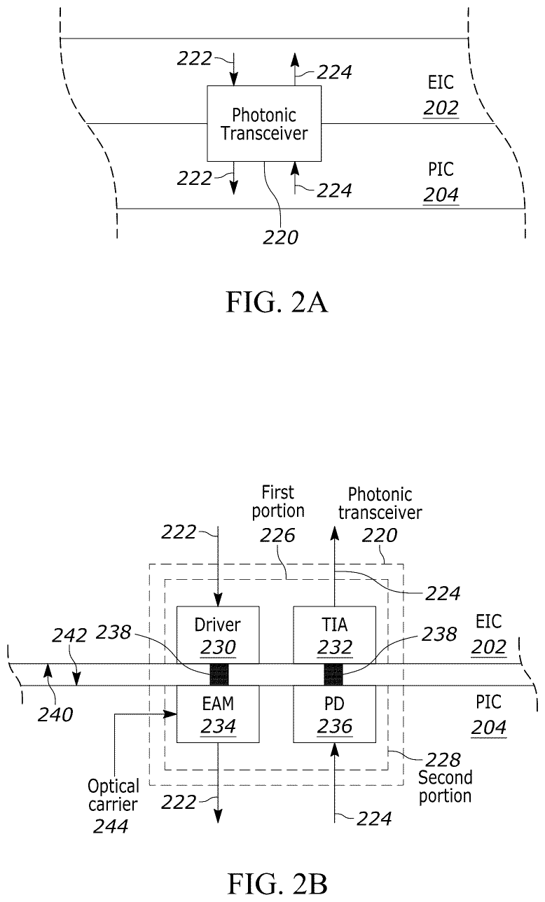

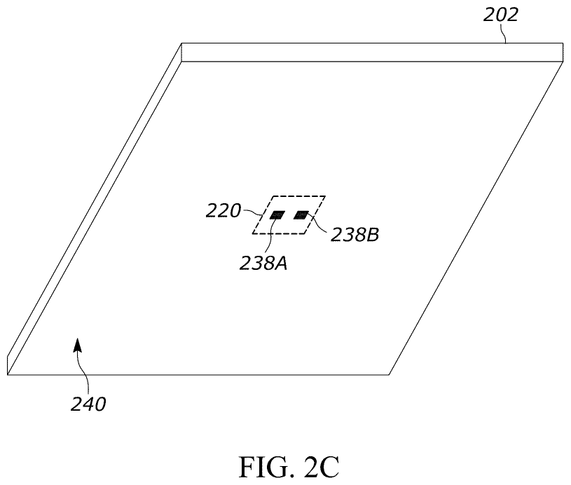

In an example, data is communicated between the EIC 102 and the PIC 104 using photonic transceivers in which each photonic transceiver includes a first portion in the EIC and a second portion in the PIC. FIG. 2A is a side view of an example photonic transceiver 220 of a memory module relative to an EIC 202 and a PIC 204 in which a portion of the photonic transceiver is embodied in the EIC and a portion of the photonic transceiver is embodied in the PIC. Although not shown in FIG. 2A, in an example memory module, the photonic transceiver is optically coupled to an external optical interface of the PIC and electrically coupled to switching circuitry of the EIC. As indicated by the arrows and as is described further below, digital data can be passed from the electrical domain of the EIC to the optical domain of the PIC (arrows 222) and digital data can be passed from the optical domain of the PIC to the electrical domain of the PIC (arrows 224). Examples of how the photonic transceivers are used to form a memory module are described below.

FIG. 2B is an expanded side view of the photonic transceiver 220 from FIG. 2A in which a first portion 226 of the photonic transceiver in the EIC 202 includes a driver 230 and an amplifier 232 (e.g., a transimpedance amplifier (TIA)) and a second portion 228 of the photonic transceiver in the PIC 204 includes a modulator 234 (e.g., an Electro-Absorption Modulator (EAM)) and a photodetector 236. The first portion of the photonic transceiver and the second portion of the photonic transceiver are electrically connected to each other by electrical interconnects 238. In an example, the first portion and the second portion of a photonic transceiver are vertically aligned with each other such that components of the first portion and the second portion overlap with each other or are very close to each other when viewed from a plan view. In an example, the electrical interconnects are copper pillars no longer than 2 millimeters and in many cases less than 200 microns and in other cases less than 50 microns. In other examples, the electrical interconnects can be solder bumps that are formed of a material such as tin, silver, or copper. If solder bumps are used for the electrical interconnects, then the solder bumps may be flip-chip bumps. In yet another example, the interconnects may be elements of a ball-grid array (BGA), pins of a pin grid array (PGA), elements of a land grid array (LGA), or some other type of electrical interconnect. Generally, the electrical interconnects may physically and electrically couple the portion of a photonic transceiver that is in the EIC to the portion of the photonic transceiver that is in the PIC. For example, one or more of the electrical interconnects may physically couple with, and allow electrical signals to pass between, conductive pads of the EIC and conductive pads of the PIC. The electrical interconnects may not have a uniform size, shape, or pitch. A finer pitch of interconnects may be desirable to allow a denser communication pathway between elements coupled to the PIC. In some implementations, the size, shape, pitch, or type of one or more of the electrical interconnects may be different than depicted in the figures, or different than others of the electrical interconnects. The specific type, size, shape, or pitch of the electrical interconnects may be based on one or more factors such as use case, materials used, design considerations, and manufacturing considerations.

In an example, the driver 230 and the amplifier 232 of the first portion 226 of the photonic transceiver 220 include electronic circuits that are fabricated in the EIC 202. In an example, the first portion of the photonic transceiver is an analog/mixed signal (AMS) block that includes circuits for processing analog signals or circuits for processing analog signals and circuits for processing digital signals. The driver of the first portion of the photonic transceiver may include digital control and analog amplifier circuits. In an example, the driver includes a driver interface (not shown) that is exposed at the bottom major surface 240 of the EIC. The amplifier of the first portion of the photonic transceiver may include a transimpedance amplifier (TIA). In an example, the amplifier includes an amplifier interface (not shown) that is also exposed at the bottom major surface of the EIC. In an example, the driver interface and the amplifier interface include one or more conductive contacts or pads that are electrically coupled to electronic circuits of the respective components and that are exposed at the bottom major surface of the EIC. FIG. 2C shows a view of the bottom major surface 240 of the EIC 202, including the driver interface 238A and the amplifier interface 238B exposed at the bottom major surface of the EIC. It should be understood that the EIC may include multiple photonic interface with corresponding driver and amplifier interfaces exposed at the bottom major surface. In an example, the driver interface and/or the amplifier interface of the EIC is slightly offset from the corresponding interconnect such that the interface does not sit directly on top of the corresponding interconnect in order to avoid parasitic capacitance.

The modulator 234 of the second portion 228 of the photonic transceiver 220 may include an Electro-Absorption Modulator (EAM) that is fabricated into the PIC 204, for example, the EAM may be a Germanium-Silicon (GeSi) EAM. Other examples of optical modulators include, but are not limited to, micro-ring resonators (MRRs), or any suitable optical component with sufficient thermal stability over the operating ranges of the photonic transceivers. In an example, the modulator has thermal stability over the operating range, a utilizes the franz-keldyish effect, utilizes a quantum confined stark effect, and/or utilizes an external thermal control to increase thermal stability. In an example, the modulator includes a modulator interface (not shown) that is exposed at the top major surface 242 of the PIC. For example, the modulator interface may include one or more conductive contacts or pads that are electrically coupled to the modulator and that are exposed at the top major surface of the PIC.

The photodetector 236 of the second portion 228 of the photonic transceiver 220 includes electronic circuits that are fabricated into the PIC 204, for example, the photodetector may be a GeSi photodetector. In an example, the photodetector includes a photodiode and a photodetector interface (not shown) that are fabricated into the PIC. For example, the photodetector interface may include one or more conductive contacts that are exposed at the top major surface of the PIC.

FIG. 2B also illustrates the passing of data from the electrical domain of the EIC 202 to the optical domain of the PIC 204 (e.g., via the arrows 222 pointing “down” into the driver 230 and out from the modulator 234) and the passing of data from the optical domain of the PIC to the electrical domain of the EIC (e.g., via the arrows 224 pointing “up” into the photodetector 236 and out from the amplifier 232). With reference to the left side of FIG. 2B, in an example operation, signals representative of digital data are applied to the driver in the EIC, which cause the driver to generate signals that are passed through the interconnect 238 and drive the modulator in the PIC. In an example, an optical carrier 244 is modulated by the modulator in response to the signals from the driver and the modulated optical carrier propagates within an optical waveguide (not shown) of the PIC. Thus, the left side of FIG. 2B illustrates the transformation of signals from the electrical domain to the optical domain between the stacked EIC and PIC. With reference to the right side of FIG. 2B, a modulated optical carrier is received at the photodetector via an optical waveguide (not shown) of the PIC. The photodetector converts the modulated optical carrier into electrical signals that are passed via the interconnect to the amplifier of the EIC. The amplifier of the EIC amplifies the electrical signals and provides the amplified electrical signals to another component of the EIC, such as to an analog-to-digital converter (ADC) of the EIC. Thus, the right side of FIG. 2B illustrates the transformation of signals from the optical domain to the electrical domain between the stacked EIC and PIC.

HBM has been widely adopted to support the memory needs of GPUs for AI workloads. While HBM can provide fast access to data, HBM is generally more expensive than other types of memory such as DDR. Regardless of the type of memory employed, the stored data must still be accessed by a GPU. Placing the memory physically close to the GPU has a benefit of power efficiency but a drawback of limited physical space around the GPU, while placing the memory further away from the GPU has the benefit of more physical space for the memory but a drawback of increased power consumption due to longer transmission distances. It has been realized that photonic transceivers formed by an EIC stacked on an PIC as described with reference to FIGS. 2A and 2B can be coupled with memory interfaces and memory management logic (e.g., a memory controller and a cache manager) in the EIC and co-packaged with high capacity memory (e.g., DDR) and high speed memory (e.g., HBM) to form a memory module that can store large amounts of data while providing fast access to the data by a GPU over an optical channel in an extremely energy efficient manner, which enables the memory module to be located farther away from the GPU with a negligible increase in power consumption.

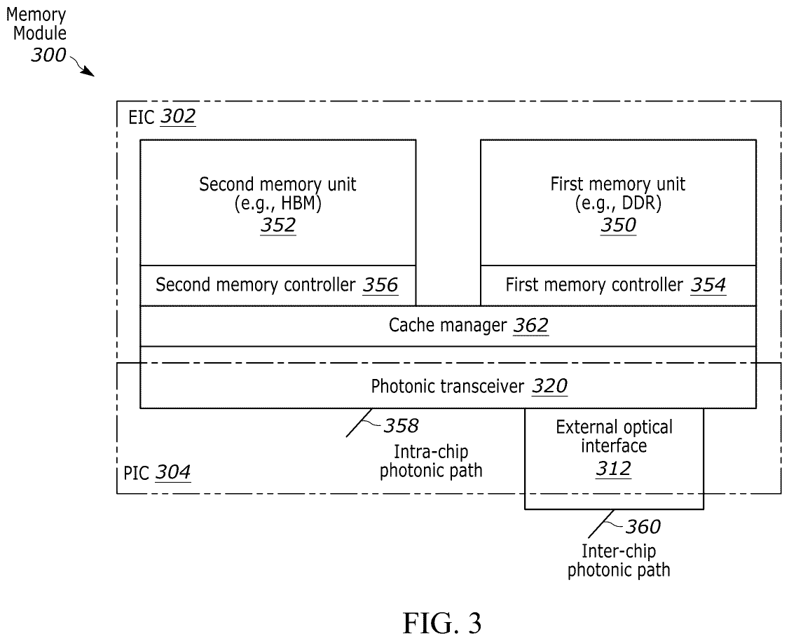

Referring to FIG. 3, in an embodiment, a memory module 300 is shown that includes an EIC 302 stacked on a PIC 304 in which at least one photonic transceiver 320 is formed between the EIC 302 and the PIC 304 as described above with reference to FIGS. 2A and 2B. The memory module 300 includes an intra chip photonic path 358 and an external optical interface 312 that is connectable to an inter chip photonic path 360. Although the memory module is described as having an intra chip photonic path 358 and an inter chip photonic path 360, the memory module may have either an intra chip photonic path or an inter chip photonic path, or some combination of multiple intra and/or inter chip photonic paths. Additionally, the photonic paths may include multiple unidirectional photonic paths. For example, the photonic paths 358 and 360 may each include a unidirectional photonic path for data that is transmitted from the memory module and a unidirectional photonic path for data that is received at the memory module. The memory module also includes a first memory unit 350 that has an electrical connection to a second memory unit 352. The memory units can be memory units in the EIC 302, for example, with a variety of potential designs capable of implementing an electrical interconnect and interfacing electronically with respective memory controllers 354 and 356, for example, to read or write data from addresses in the memories 350 and 352. In an example, the first memory controller 354 (e.g., a DDR memory controller) and the second memory controller 356 (e.g., an HBM memory controller) utilize memory control components and techniques as are known in the field. In other examples, the first memory unit 350 and/or the second memory unit 352 are external to the EIC as described with reference to FIG. 1B. The memory units 350 and 352 can include any suitable memory type, including, for example, DDR and/or HBM. In one embodiment, the first memory unit 350 is selected from memory types that generally allow for a large amount of data to be stored, whereas the second memory unit 352 is selected from memory types that generally allow for high speed.

This can include, for example, using DDR as the type of memory for the first memory unit 350 and HBM as the type of memory for the second memory unit 352. In this manner, the fast memory (e.g., HBM) can act as a cache for the slower memory (e.g., DDR) and can enhance the performance of the memory module. Although the first and second memory units are shown as singular memory units, it should be understood that the first memory unit 350 may include multiple memory units, such as multiple separately packaged DDR units and the second memory unit 352 may include multiple memory units, such as multiple separately packaged HBM units.

In an example where the memory module 300 is a component of an AI accelerator or performing Deep Learning Recommendation Model (DLRM), it may be advantageous to store embedding tables in, for example, the first memory unit 350 (e.g., DDR) and extract tensors from the embedding table into the second memory unit 352 (e.g., HBM as cache memory) in advance of a read operation (e.g., a read request from a GPU) on the cache from a local or remote node. In an example, the tensors are a format specific to DLRM but various embodiments are not limited in the type of data structure that is used, whether it is a tensor, an array, a string, a series of bits etc. A datum is used herein to refer more generically to a tensor for DLRM, or to any other data structure, packet, or sequence of bits that can be used in a computer processing environment. To this end, a cache manager 362 of the EIC 302 can be configured to obtain a datum from the first memory unit 350 (e.g., a row from the embedding table or any other datum in a different application), optionally modify the datum, and write the datum to the second memory unit 352 (e.g., the cache). Once loaded, the cache can be used in an execution environment, such as a DLRM application, wherein the described cached datum (modified or unmodified) can be provided on a unidirectional photonic link 358 and/or 360, one end of which is associated with the memory module 300, for transmitting the datum in an optical form, either through the inter-chip photonic link 360 or the intra-chip photonic link 358. Similarly, a local or remote processor at the other end of the unidirectional photonic link can request to read a datum from the cache, in which case the read request is received via the photonic path 358 or 360 and transformed to electrical form in the photonic transceiver 320. In the case of photonic path 360, the remote link uses an external optical interface 312 (e.g., an FAU) between the photonic transceiver 320 and an optical waveguide (e.g., an optical fiber or optical fibers) that carry the optical signal to its destination or receive an optical signal from a source. The other end of these photonic paths 358 or 360 can be, for example, a local or remote processor or node that utilizes the datum in the cache. Various topologies are possible.

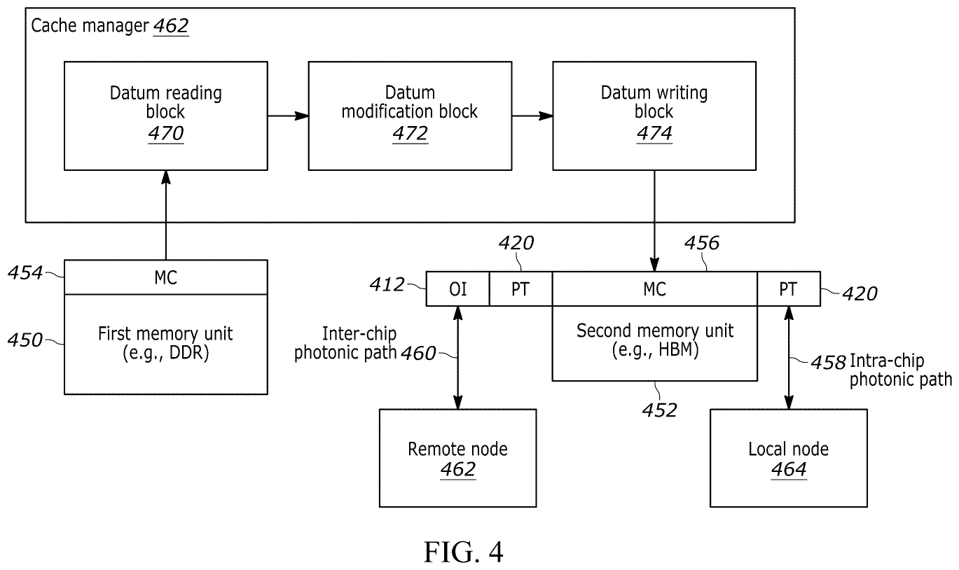

FIG. 4 is an expanded view of an example of a cache manager 462, which is similar to the cache manager 362 from FIG. 3, for the first memory 450 and the second memory unit 452 according to one embodiment. The cache manager 462 is connected to the first memory unit 450 (e.g., DDR) through the memory controller 454 and to the second memory unit 452 (e.g., HBM) through the memory controller 456. The memory controller 456 of the second memory unit 452 (e.g., HBM) is in data communication with photonic transceivers 420. One photonic transceiver 420 is optically connected to an external optical interface 412 (e.g., an FAU), which is optically connected to a remote node 462 (e.g., a GPU) via an inter chip photonic path 460 (e.g., an optical fiber or optical fibers). The other photonic transceiver 420 is optically connected to a local node 464 (e.g., a local processor) via an intra chip photonic path 458 (e.g., via an optical waveguide within the PIC).

In the example of FIG. 4, the cache manager 462 includes a datum reading block 470, an optional datum modification block 472, and a datum writing block 474. The datum reading block 470 is configured to obtain a datum from the first memory unit 450 (e.g., a large capacity, relatively slow form of memory such as DDR) using the memory controller 454. In this way, the datum reading block 470 accesses an address in the first memory unit that stores a tensor, or other data structure, that is used by the application. In one example, this could include portions of embedding tables that are used for DLRM. In this application, the needs of the DLRM application may require that embedding tables consume a large amount of memory, in which case it is advantageous to save cost and use a slower, higher capacity memory such as DDR that is suitable for such large embedding tables. One skilled in the art will note that the current advantages apply equally well to a general-purpose computing process that might also require a massive amount of memory space to carry out its work.

When data is obtained from the first memory unit 450 (e.g., DDR), the datum modification block 472 may optionally make modifications to the datum or any addresses allocated to the datum, if optimizations are used by the application. This could include, for example, rotating the address portion of the datum, exchanging positions in the datum between a first and a second portion of the datum, rotating a bit portion of the datum from a rightmost position to a leftmost position and an address portion of the datum from a leftmost position to a rightmost position in the datum. Other types of modifications could be made to the datum. If modifications are used, the modified datum is written to the second memory unit 452 (e.g., HBM) by the datum writing block 474, otherwise, the unmodified data is written to the second memory unit 452 at the address space it was originally allocated, for example. Various caching schemes can be used including a direct mapped cache and a writing of the datum to a plurality of rows in the cache. Although the cache manager is shown with the optional datum modification block, the cache manager could be implemented without such a datum modification block.

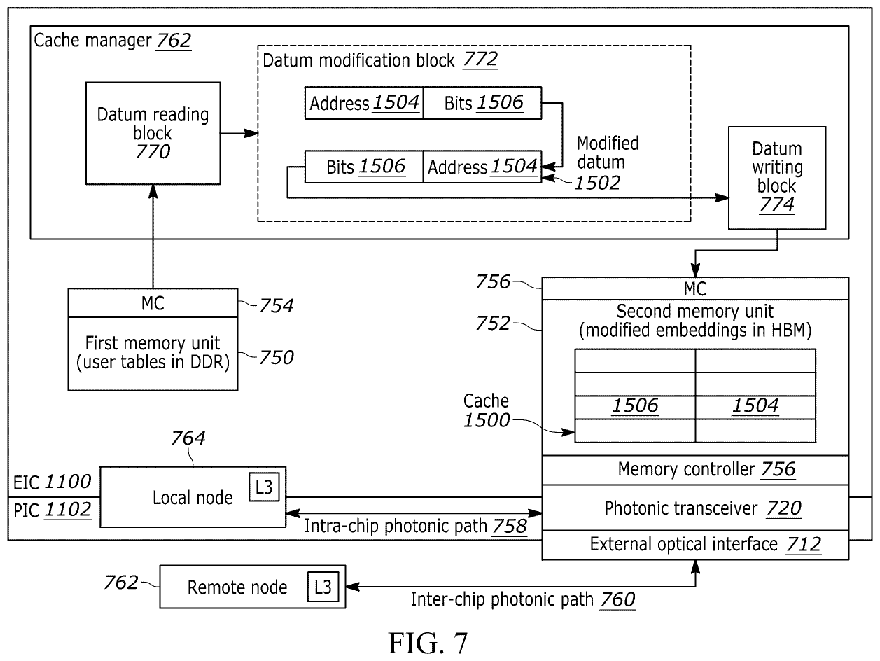

In an execution environment, a local or remote process may have a memory read operation scheduled with respect to a datum in a cache (e.g., see FIGS. 7, 1500) of the second type of memory such as second memory unit 452. In such a case, either the inter-chip photonic path 460 or the intra-chip photonic path 458 may be utilized, in which case, the transmit operation of the photonic transceiver 420 in the memory module will be to return the data along a corresponding unidirectional optical link in the opposite direction to the local or remote process.

In an example, the operations of the cache manager 462 are implemented in the EIC 402 in hardware, software, or a combination of hardware and software. For example, the EIC may be an ASIC that is configured to implement the cache manager 462, including the datum reading block 470, the datum modification block 472, and the datum writing block 474.

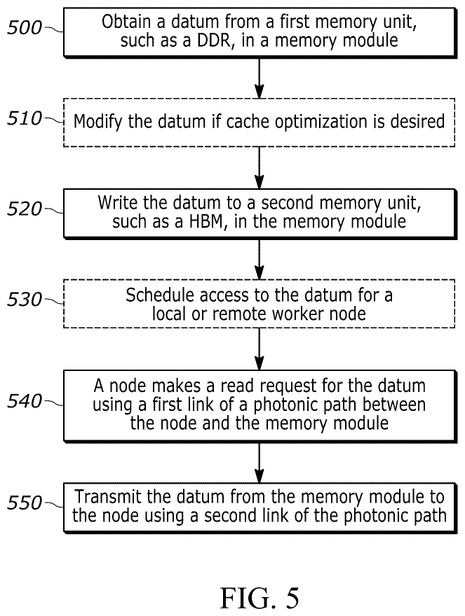

FIG. 5 is a flowchart showing how an embodiment of a memory module operates. At operation 500, a datum is obtained from a first memory unit, such as a DDR, in the memory module. In other embodiments, another type of memory can be used. The datum or its allocated address is modified at operation 510, if cache optimization is desired. This could include, for example, rotating, or otherwise modifying the datum. At operation 520, the datum is written to a second memory unit, such as a HBM, in the memory module. In other embodiments, another type of memory can be used. At operation 530, access to the datum is scheduled for a local node (e.g., a node connected directly to the PIC) or remote node (e.g., GPU). A local or remote node makes a read request for the datum at operation 540 using a first link of a photonic path between the node and the memory module. At operation 550, the datum is transmitted from the memory module to the node using a second link of the photonic path.

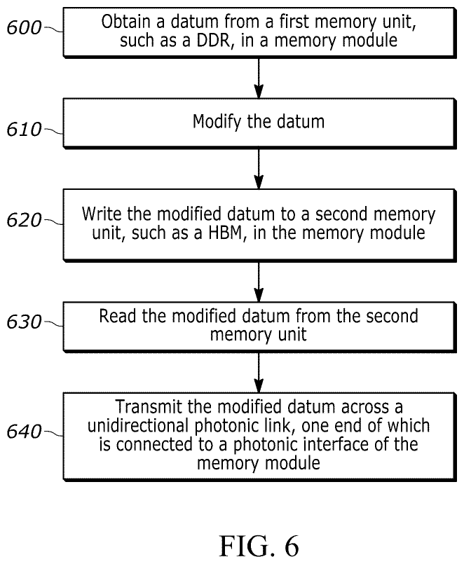

FIG. 6 is a flowchart showing how another embodiment of a memory module operates. At operation 600, a datum is obtained from a first memory unit, such as a DDR, in a memory module. At operation 610, the datum (e.g., the data) is modified. At operation 620, the modified datum is written to a second memory unit, such as HBM, in the memory module (potentially at a different address, for example). At operation 630, the modified datum is read from the second memory unit. At operation 640, the modified datum is transmitted across a unidirectional photonic link, one end of which is connected to a photonic transceiver of the memory module. For example, the memory module transmits the data as optical signals via the photonic transceiver to a remote node such as a GPU.

FIG. 7 is a diagram of a memory module having first and second memory units 750 and 752, respectively, according to another embodiment. In the example, a cache manager 762 includes a datum reading block 770, an optional datum modification block 772, and a datum writing block 774 as described with reference to FIG. 4. The datum reading block 770 is configured to obtain a datum from the first memory unit 750 (e.g., a large capacity, relatively slow form of memory such as DDR) through the memory controller 754. In this way, the datum reading block 770 accesses an address in memory that stores a datum. In one example, this could include portions of embedding tables that are used for DLRM. In this application, the needs of the DLRM application may require that embedding tables consume a large amount of memory, in which case it may be advantageous to save cost and use a slower, higher capacity memory such as DDR that is suitable for such large embedding tables. One skilled in the art will note that the current advantages apply equally well to a general-purpose computing process that might also require a massive amount of memory space to carry out its work.

When data is obtained from the first memory unit 750, the datum modification block 772 may optionally make modifications to the datum or to any addresses allocated to the data. This could include, for example, rotating the datum, exchanging positions in the datum between a first and a second portion of the datum, rotating a bit portion of the datum from a rightmost position to a leftmost position and an address portion of the datum from a leftmost position to a rightmost position in the datum, or other types of modification to the datum. In this example, an address portion 1504 of the datum and a bit portion 1506 of the datum are rotated to generate the modified datum 1502, although it should be understood that the contents of the datum need not be modified but only the allocated address associated with the datum. Further, it should be understood that other types of modifications to the datum are possible. The modified datum 1502 can be written to the second memory unit 752 by the datum writing block 774 through the memory controller 756, for example, to cache 1500. Various caching schemes can be used including, for example, a direct mapped cache and a writing of the datum to a plurality of rows in the cache 1500. For embedding tables, modifying the address space for the data may be beneficial because each row (which can be composed of multiple cache lines) can be mapped to different parts of the cache. The effect is that more of the cache is used by spreading out the usage to the entire cache, rather than just clumps of the cache. This may improve the effective cache hit rate of a direct-mapped cache according to various embodiments. For such a large cache, direct mapping is generally used in various examples to reduce or minimize the cache overhead. In an execution environment, a local node 764 or remote node 762 may have a memory read operation scheduled with respect to the modified datum 1502 in the cache 1500 of the second memory unit 752. In such a case, either an inter-chip photonic path 760 or intra-chip photonic path 758 might be utilized, in which case, the transmit operation of the photonic transceiver 720 in the memory module will be to return the data along a unidirectional link in the opposite direction to the local or remote process.

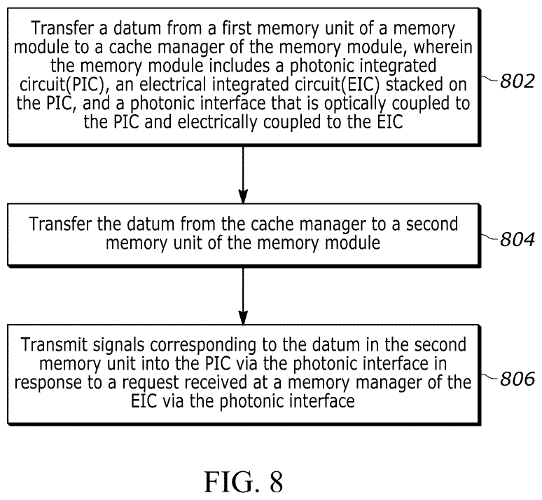

FIG. 8 is a process flow diagram of an example of a method for operating a memory module such as the memory module described herein. At block 802, a datum is transferred from a first memory unit of a memory module to a cache manager of the memory module, wherein the memory module includes a PIC, an EIC stacked on the PIC, and a photonic interface that is optically coupled to the PIC and electrically coupled to the EIC. At block 804, the datum is transferred from the cache manager to a second memory unit of the memory module. At block 806, signals corresponding to the datum in the second memory unit are transmitted into the PIC via the photonic interface in response to a request received at a memory manager of the EIC via the photonic interface.

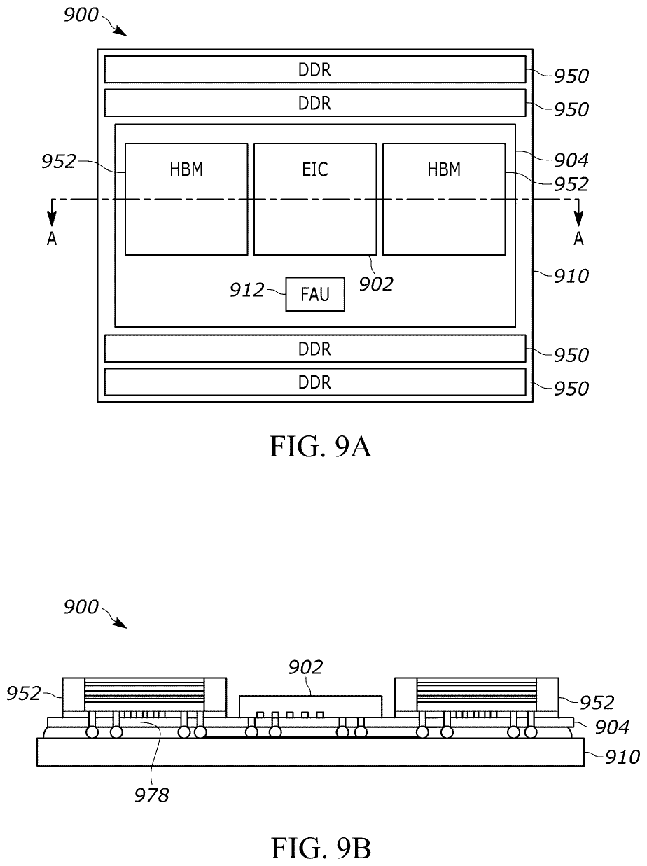

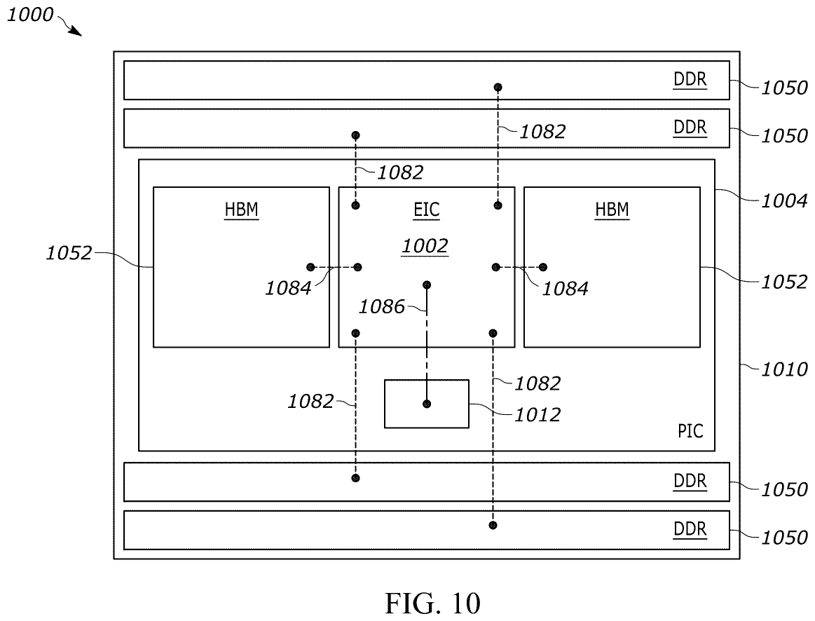

FIG. 9A is a top view of an example of a memory module 900 that includes an EIC 902 stacked on a PIC 904. The top view of the memory module shows a substrate 910, the PIC 904, and the EIC 902, four DDR units 950 (first memory units), two HBM units 952 (second memory units), and an external optical interface 912 (e.g., an FAU). In the example of FIG. 9A, the DDR units are physically attached directly to the substrate and the HBM units are physically attached directly to the PIC.

FIG. 9B is a side view of the memory module 900 shown in FIG. 9A at cross-section AA. The side view shows the substrate 910, the PIC 904, the EIC 902, and the two HBM units 952 mounted on the PIC 904. As shown in FIG. 9B, there may be various electrical interconnects (e.g., vias 978) between the EIC and the substrate, between the PIC and the substrate, and between the HBM units and the substrate.

FIGS. 9A and 9B provide an example of the spatial relationships between components of the example memory module 900. Although FIGS. 9A and 9B are provided as one example of the spatial relationship between components of the memory module, other arrangements and corresponding spatial relationships are possible.

FIG. 10 is a top view of a memory module 1000 similar to the top view of FIG. 9A, which illustrates signal paths between the EIC 1002, the PIC 1004, the DDR units 1050 (first memory units), and the HBM units 1052 (second memory units). In the example of FIG. 10, there is an electrical signal path 1082 between the EIC 1002 and each one of the four DDR units 1050. In an example, the electrical signal paths 1082 include an electrical PHY interface within the EIC for each DDR unit, an electrical signal path on and/or within the substrate and the PIC, and an electrical PHY interface within each DDR unit. Thus, in this example, the EIC will have four different PHY interfaces that are specific to DDR units within the EIC. Typically, these PHY interfaces for the DDR will be at or near a perimeter edge (e.g., the beachfront) of the EIC. In the example of FIG. 10, there is also an electrical signal path 1084 between the EIC 1002 and each one of the two HBM units 1052. In an example, the electrical signal paths 1084 include an electrical PHY interface within the EIC for each HBM unit, an electrical signal path in the substrate and the PIC, and an electrical PHY interface within each HBM unit. In an example, the electrical signal paths in the PIC include vertical conductive vias and the signal paths on and/or within the substrate include horizontal and vertical conductive paths. Thus, in this example, the EIC will have two different PHY interfaces that are specific to HBM units within the EIC. Typically, the PHY interfaces for the HBM will also be at or near the perimeter edge (e.g., the beachfront) of the EIC.

In the example of FIG. 10, there is an optical signal path 1086 between the external optical interface 1012 (e.g., FAU) and the EIC 1002. For example, the optical signal path includes the external optical interface 1012 (e.g., an FAU), an optical waveguide within the PIC 1004, and a photonic transceiver that is formed between the PIC and the EIC that is stacked on the PIC. In particular, the photonic transceiver includes a first portion in the EIC and a second portion in the PIC. As described above with reference to FIGS. 2A and 2B, the first portion in the EIC includes a driver and an amplifier and the second portion in the PIC includes a modulator and a photodetector. In an example, a memory module may include multiple optical signal paths between the EIC and the external optical interface and multiple corresponding photonic transceivers that are formed between the PIC and the EIC that is stacked on the PIC. Additionally, the memory module may utilize optical multiplexing and/or demultiplexing to increase the bandwidth capacity of the memory module.

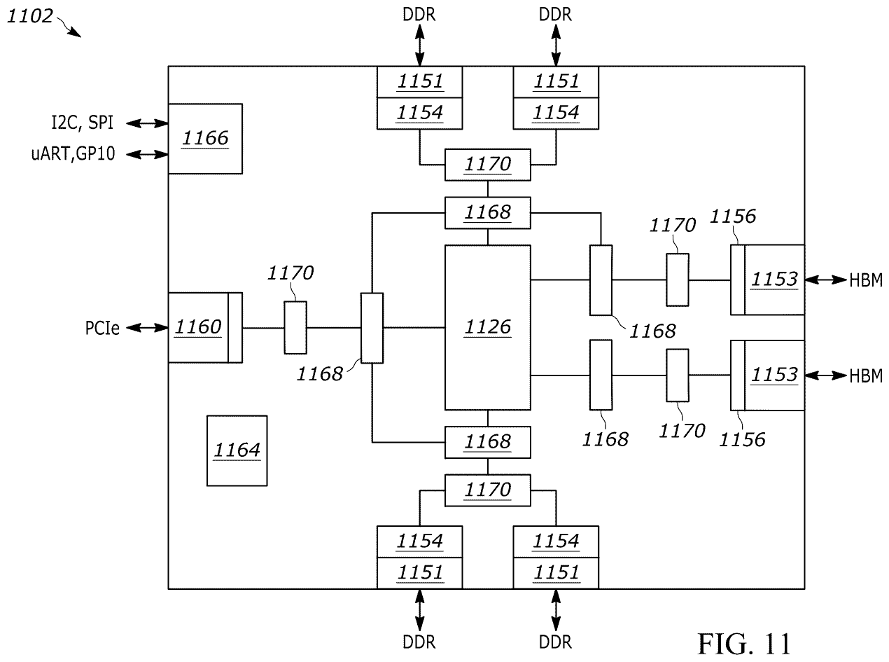

FIG. 11 is a top view of an example EIC 1102 that shows various functional blocks that may be fabricated within the EIC. Of particular note, the top view shows four PHY interfaces 1151 and corresponding memory controllers 1154 that are specific to DDR units, two PHY interfaces 1153 and corresponding memory controllers 1156 that are specific to HBM units, and a first portion 1126 of at least one photonic transceiver as described above with reference to FIGS. 2A and 2B. In the example of FIG. 11, the EIC includes multiple first portions of photonic transceivers that are configured to support sixteen optical channels although photonic interfaces that support more or less than sixteen optical channels are possible. As shown in FIG. 11, the DDR PHY interfaces 1151 and the HBM PHY interfaces 1153 are located at a perimeter edge (e.g., the beachfront) of the EIC while the first portions of the photonic transceivers are located in an interior region of the EIC (e.g., not at the perimeter edge or beachfront). Such a configuration of input/output (I/O) interfaces can help to increase the density of I/O interfaces on the EIC. In an example, the DDR PHY interfaces and the HBM PHY interfaces are equidistant from the first portion of the at least one photonic interface, e.g., equidistant within about 20%, or within about 10%. Having the DDR PHY interfaces and the HBM PHY interfaces equidistant from the first portion of the at least one photonic interface can even out transmission times within the EIC, which can be helpful in traffic management and/or traffic scheduling through the EIC.

In the example, the DDR PHY interfaces 1151 handle low-level physical signaling, timing, and calibration for data transmission to and from a DDR unit. The memory controllers 1154 corresponding to the DDR PHY interfaces 1151 manage high-level data flow, command sequencing, and memory operations. Likewise, in an example, the HBM PHY interfaces 1153 ensure the physical integrity of high-speed and low-power data transfers across the wide HBM interface. The memory controllers 1156 corresponding to the HBM PHY interfaces 1153 manage high-level memory operations, multi-channel data flows, and scheduling.

In the example, the first portion 1126 of the photonic transceivers include drivers and amplifiers as described above. The first portion of the photonic transceivers may also include a photonic fabric (PF) agent component, a flow control unit (Flit) management component, and a physical coding sublayer (PCS).

An EIC of a memory module may also include other components. In the example of FIG. 11, the EIC 1102 also includes a high-speed I/O interface 1160 such as a Peripheral Component Interface express (PCIe) or Universal Chiplet Interconnect express (UCIe) interface, a processor core 1164 (or cores), other I/O interfaces 1166 (e.g., SPI, I2C, UART, GPIO), crossbar circuitry 1168, and crossbar agents 1170. In an example, a read or write request may be received at the high-speed I/O interface 1160 while the data is transferred to/from the memory module via the first portion 1126 of the at least one photonic transceiver.

In an example, the cache manager and memory controller(s) as described herein may be implemented in the EIC via general processors and/or custom circuitry. For example, at least some of the functionality of the cache manager and/or memory controller may be implemented in computer readable code that is executed on an on-chip processing core. In other examples, at least some of the functionality of the cache manager and/or memory controller are implemented in application specific circuitry that is fabricated in the EIC.

As described above, the EIC and the PIC may be fabricated as separate devices and then physically and electrically coupled to each other via electrical interconnects. In one example, the EIC alone includes novel features of a first memory interface (e.g., a DDR PHY interface), a second memory interface (e.g., an HBM PHY interface), a first portion of a photonic transceiver, the first portion of the photonic transceiver including a driver and a driver interface that is electrically coupled to the driver and exposed at a bottom major surface of the EIC and an amplifier and an amplifier interface that is electrically coupled to the amplifier and exposed at a bottom major surface of the EIC, a cache manager between the first memory interface and the second memory interface, a memory controller between the first portion of the photonic transceiver and the second memory interface, wherein the cache manager is configured to 1) obtain a datum from a first memory, via the first memory interface, and 2) provide the datum to a second memory, via the second memory interface, and wherein the memory controller is configured to 1) receive a request via the first portion of the photonic interface to read or write to the first memory, and 2) transmit driver signals that correspond to the datum in the second memory to the driver interface of the first portion of the photonic transceiver in response to a request.

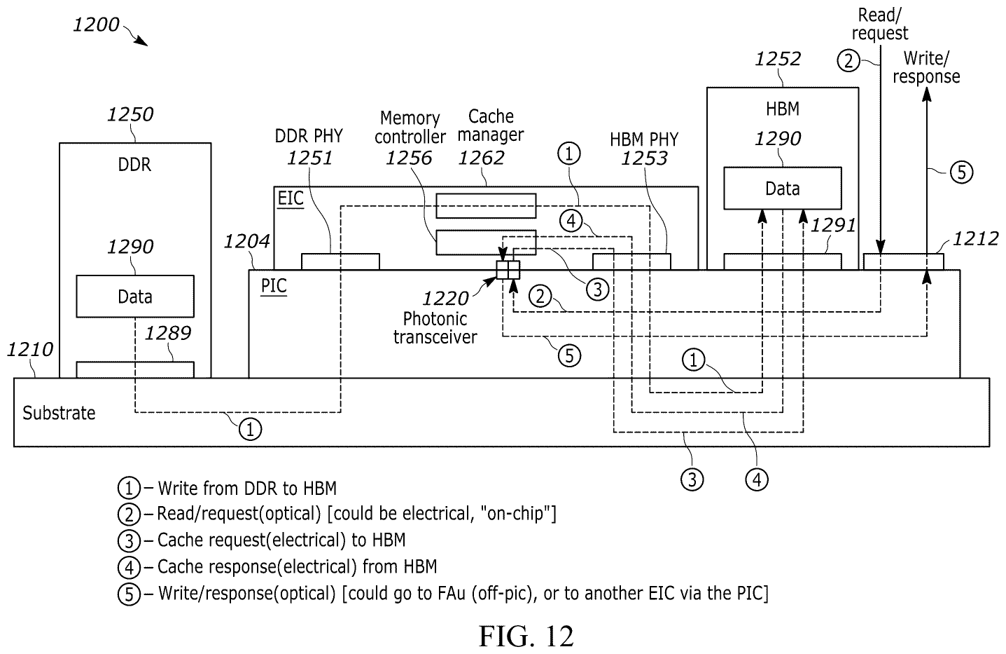

FIG. 12 is a side cutaway view of a memory module 1200 that includes a substrate 1210, a PIC 1204, and an EIC 1202 stacked on the PIC, a DDR unit 1250 (first memory unit) mounted on the substrate, an HBM unit 1252 (second memory unit) mounted on the PIC, and an external optical interface 1212 (e.g., an FAU). The side cutaway view includes signal paths that illustrate an example of a memory transaction between the memory module and an external device such as a GPU (not shown) via the external optical interface, similar to an operation described with reference to FIG. 7. The example memory transaction illustrated in FIG. 12 is a memory read request made by the external device and received via the external optical interface 1212. In the example, the requested data is stored in the DDR unit 1250, cached in the HBM unit 1252, and then transmitted out the external optical interface 1212 of the memory module via at least one photonic transceiver 1220 of the memory module. In an example, the EIC includes a first memory interface (e.g., DDR PHY interface 1251) and a second memory interface (e.g., HBM PHY interface 1253), and the second memory interface has a higher data transfer speed than the first memory interface.

The example memory transaction illustrated in FIG. 12 is broken down into five operations that are illustrated and labeled in FIG. 12 and described herein. In operation one, data 1290 that is stored in the DDR unit 1250 is written from the DDR unit (via electrical PHY interface 1289) to the HBM unit 1252. In an example, a cache manager 1262 of the EIC 1202 determines that the data should be written from the DDR unit to the HBM unit and orchestrates the write operation. The cache manager may decide to write the data from the DDR unit to the HBM unit for various reasons, such as dictated by DLRM. In an example, the cache manager 1262 may perform some operation on the data 1290, which may include modifying the data. In one example, the cache manager may modify the data as described above with reference to FIGS. 6 and 7.

In operation two, a read request is received at the memory module 1200 via the external optical interface 1212 and passed as optical signals via the PIC 1204 and the photonic transceiver 1220 to the EIC 1202. As illustrated in FIG. 12, the read request is received by a memory controller 1256 of the EIC.

In operation three, the memory controller 1256 orchestrates a cache request to the HBM unit 1252 in response to the read request. For example, the memory controller communicates with the HBM unit to determine if the requested data 1290 is held in the HBM unit. The communications between the EIC 1202 and the HBM unit 1252 are via electrical signals, with the electrical signals passing through an HBM PHY interface 1253, through the PIC 1204 through vertical conductive vias, and through the substrate 1210 to an electrical PHY interface 1291 of the HBM unit via horizontal and vertical conductive paths.

In operation four, the requested data 1290 is indeed held in the HBM unit 1252 and thus the data 1290 is transmitted to the memory controller 1256 of the EIC 1202 from the HBM unit as electrical signals via the electrical signal path that includes an electrical PHY interface 1291 of the HBM unit, the PIC 1204, the substrate 1210, and the electrical PHY interface 1253 of the EIC.

In operation five, the data 1209 that is received at the EIC 1202 from the HBM unit 1252 is transmitted via the photonic transceiver 1220 to the external optical interface 1212 of the memory module 1200. In particular a driver of a first portion of the photonic transceiver that is in the EIC drives a modulator of a second portion of the photonic transceiver that is in the PIC to generate optical signals that are transmitted via optical waveguides through the PIC and out the external optical interface of the memory module. The optical signals are modulated to carry the data that was cached in the HBM unit and requested by another device (e.g., a GPU).

In the example of FIG. 12, the requested data 1290 is transmitted via electrical signals over relatively short distances between the memory units (DDR 1250 and HBM 1252) and the EIC 1202 but transmitted over a relatively longer distance between the memory module 1200 and the external device (e.g., GPU)(not shown) via optical fibers and optical signals. Thus, the memory module can provide the benefits of DDR memory (large and cheap) and the benefits of HBM memory (fast) along with the benefits of an optical interconnect between the memory module and an external device (e.g., a GPU), which enables high data transfer speeds over longer distances and at lower power consumption. Although the example of FIG. 12 only includes one DDR unit 1250 (first memory unit) and one HBM unit 1250 (second memory unit), a memory module can include multiple separately packaged DDR units and/or multiple separately packaged HBM units, e.g., as described with reference to FIGS. 9A and 9B. Although the memory transaction described with reference to FIG. 12 is a memory read request, memory write requests and the corresponding data can be passed from an external device (e.g., a GPU) via the external optical interface 1212 and the photonic transceiver 1220.

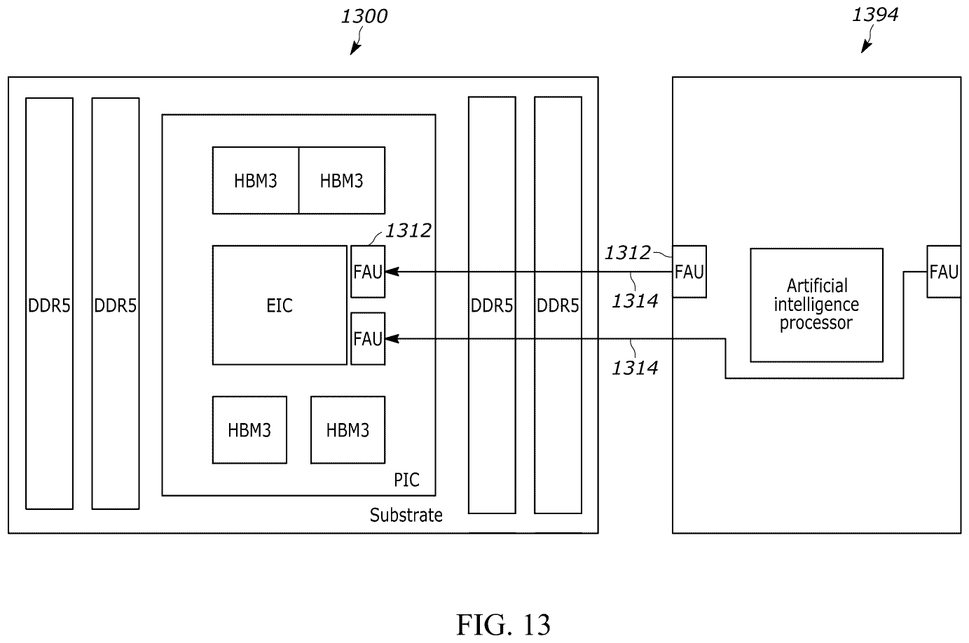

As described with reference to FIG. 12, the memory module may receive read requests from an external device such as a GPU. FIG. 13 depicts an example of a memory module that is connected to a GPU 1394 by an optical interconnect. In the example of FIG. 13, the GPU is packaged together with an optical interconnect 1312 (e.g., an FAU) and the optical interconnect of the memory module 1312 is optically connected to the optical interconnect 1312 of the GPU 1394 by one or more optical fibers 1314. In such an example, the GPU issues a read request that is communicated to the memory module via optical signals and the memory module processes the read request as described with reference to FIG. 12. In an example, the GPU may be physically located within about 0.2 - 2.0 meters from the GPU.

In the example shown in FIG. 13, the memory module and the GPU both include a single external optical interface 1212 (e.g., FAU), which may include 8-32 separate optical fibers. The external optical interconnect may support more or less than 8-32 separate optical fibers. Additionally, more than one external optical interconnect may be included on the memory module to connect with the GPU to increase the bandwidth between the memory module and the GPU.

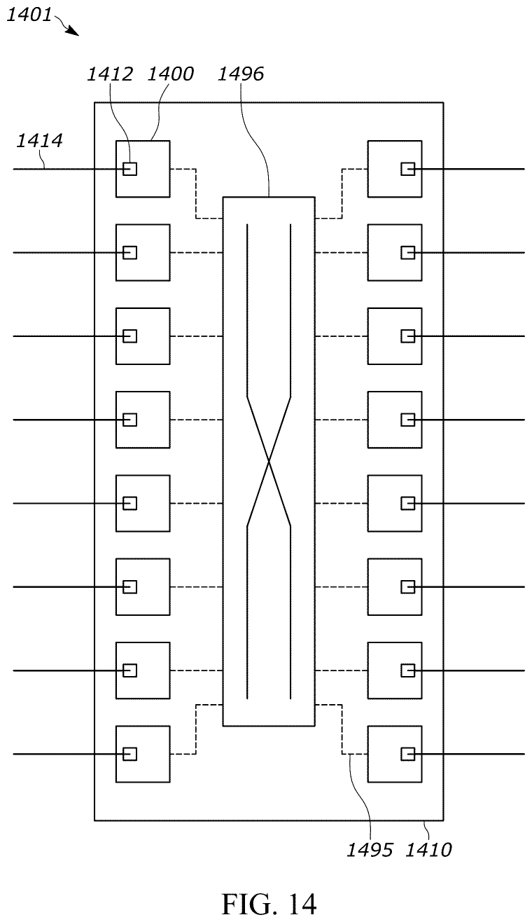

In another example, multiple memory modules may be aggregated together into a single optical memory appliance. FIG. 14 depicts an example of an optical memory appliance 1401 that includes sixteen memory modules 1400 that are interconnected to each other by a crossbar 1496. In the example of FIG. 14, the sixteen memory modules and the crossbar are physically mounted on a substrate 1410 that includes electrical signal paths 1495 to interconnect the memory modules and the crossbar. The memory modules are similar to, or the same as, the memory modules described herein and each memory module includes an external optical interface 1412 that can be connected to an optical interface of another device such as a GPU by an optical fiber 1414, or optical fibers. In the example, the memory modules each include an electrical interface (not shown), such as a PCIe or UCIe interface, which is electrically connected to a compatible electrical interface on the crossbar. In the example of FIG. 14, the crossbar is an IC device that includes sixteen electrical interfaces (e.g., PCIe/UCIe) that are compatible with the electrical interfaces of the interfaces of the memory modules. Given the configuration of the optical memory appliance 1401 shown in FIG. 14, a read request received at any one of the memory modules via an external optical interface of the memory module can be serviced by data that is stored in any one of the sixteen memory modules of the optical memory appliance. For example, a memory module that receives a read request can locate the requested data in another memory module in the optical memory appliance, fetch the requested data via the crossbar, and then optically transmit the data to the requesting device (e.g., a GPU) via its photonic transceivers and its external optical interface.

Thus, the storage capacity of an optical memory appliance can be significantly scaled beyond the capacity of a single memory module without having to redesign the memory module.

Although not shown in FIG. 14, the optical memory appliance 1401 may also include one or more light engines (e.g., laser light sources). In one example, the optical memory appliance includes four light engines for each memory module, with each of the four light engines generating an optical carrier signal at a different wavelength. In an example, an optical memory appliance with sixteen memory modules can provide 1 TB of HBM and 32 TB of DDR, and may support up to 7.2 Tb per second (Tbps) per channel, for a total bandwidth capacity of 115 Tbps (7.2 Tbps×16 channels=115 Tbps).

Memory modules as described herein can be scaled up to increase storage capacity and/or access bandwidth by, for example, increasing the number of IP blocks on a single EIC. With reference back to FIG. 11, the EIC 1102 can be scaled up to include additional first portions of photonic transceivers, additional DDR PHY interfaces additional HBM PHY interfaces, and/or additional PCIe, or UCIe, interfaces. In one example, the configuration of the EIC shown in FIG. 11 may support the following bandwidths:
Photonic transceivers: 1.8 Tbps×4=7.2 Tbps;
HBM: 3.6 Tbps×2=7.2 Tbps;
DDR5: 350 Gbps×4=1.4 Tbps;
PCIe: 64 Gbps×16=2 Tbps.

In another example, an EIC can be scaled up by including eight photonic channels, four first portions of photonic transceivers, and four HBM PHY interfaces, e.g., two additional HBM PHY interfaces. A memory module configured this way may support the following bandwidths:
Photonic transceivers: 1.8 Tbps×8=57.6 Tbps;
HBM: 3.6 Tbps×4=28.8 Tbps;
DDR5: 350 Gbps×4=1.4 Tbps;
PCIe: 64 Gbps×16=2 Tbps.

In an example, the memory module is embodied as a Co-Packaged Optics (CPO) device and/or as a System-in-Package (SiP) device. In such CPO and SiP devices, optical components (e.g., the PIC) and electrical components (e.g., the EIC) are packaged into a single device.

The terms “optical” and “photonic” are be used interchangeably herein to refer to electromagnetic signals and/or corresponding hardware that is designed to generate, manipulate, receive electromagnetic energy in wavelength ranges around 1,310 nm and 1,550 nm, although other wavelength ranges are possible.

Additional disclosure herein includes a method comprising obtaining a datum from a first type of memory in a memory package; writing the datum to a second type of memory in the memory package, receiving a read request for the datum across a first photonic link, a receive portion of the first photonic link being associated with the memory package, and transmitting the datum across a second photonic link, a transmit portion of the second photonic link being associated with the memory package. In an example, the method may further comprise modifying the datum. In an example, the datum has an address portion and a bit portion. In an example, the operation of modifying comprises rotating the bit portion. In an example, first type of memory includes one or more of NAND Flash memory, solid-state drive (SSD) memory, NOR Flash memory, conventional CMOS memory, thin film transistor-based memory, phase change memory (PCM), storage class memory (SCM) such as Optane, magneto-resistive memory (MRAM), resistive RAM (ReRAM or RRAM), and traditional DRAM (including HBM and DDR-based DRAM. In an example, the second type of memory includes one or more of NAND Flash memory, solid-state drive (SSD) memory, NOR Flash memory, conventional CMOS memory, thin film transistor-based memory, phase change memory (PCM), storage class memory (SCM) such as Optane, magneto-resistive memory (MRAM), resistive RAM (ReRAM or RRAM), and traditional DRAM (including HBM and DDR-based DRAM

Additional disclosure herein includes a memory appliance comprising one or more first memory units; one or more second memory units, a cache manager configured to obtain a datum from the first memory units and write the tensor to the second memory units, a first photonic link, one end of which has a receiver associated with the memory appliance, for receiving a request for the datum, and a second photonic link, one end of which has a transmitter associated with the memory appliance, for transmitting the modified datum. In an example, the first memory units include one or more of NAND Flash memory, solid-state drive (SSD) memory, NOR Flash memory, conventional CMOS memory, thin film transistor-based memory, phase change memory (PCM), storage class memory (SCM) such as Optane, magneto-resistive memory (MRAM), resistive RAM (ReRAM or RRAM), and traditional DRAM (including HBM and DDR-based DRAM. In an example, the second memory units include one or more of NAND Flash memory, solid-state drive (SSD) memory, NOR Flash memory, conventional CMOS memory, thin film transistor-based memory, phase change memory (PCM), storage class memory (SCM) such as Optane, magneto-resistive memory (MRAM), resistive RAM (ReRAM or RRAM), and traditional DRAM (including HBM and DDR-based DRAM. In an example, the cache manager is configured to rotate the datum.

The connections as discussed herein may be any type of connection suitable to transfer signals or power from or to the respective nodes, units, or devices, including via intermediate devices. The connections may be illustrated or described in reference to being a single connection, a plurality of connections, unidirectional connections, or bidirectional connections. However, different embodiments may vary the implementation of the connections. For example, single connections carrying multiple signals may be separated out into various different connections carrying subsets of these signals. The term “coupled” or similar language may include a direct physical connection or a connection through other intermediate components even when those intermediate components change the form of coupling from a source to a destination.

The present disclosure provides computing systems, implemented by one or more circuit packages (e.g., SIPs), that achieve reduced power consumption and/or increased processing speed. In accordance with various embodiments, power consumed for, in particular, data movement is reduced by maximizing data locality in a circuit package and reducing energy losses when data movement is needed. Power-efficient data movement, in turn, can be accomplished by moving data over small distances in the electronic domain, while leveraging photonic channels for data movement in scenarios where the resistance in the electronic domain and/or the speed at which the data can move in the electronic domain leads to bandwidth limitations that cannot be overcome using existing electronic technology. Thus, in some embodiments, each circuit package includes an electronic integrated circuit (EIC) that includes memory management components and photonic transceivers that are connected by bidirectional photonic channels (e.g., implemented in a PIC in a separate layer or chip of the package) into a hybrid, electronic-photonic (or electro-photonic) multiport network switch. The memory module may be connected, by bidirectional photonic channels, to other memory modules and/or network nodes (e.g., compute nodes and/or memory nodes).

As described herein, the present disclosure includes a number of practical applications having features described herein that provide benefits and/or solve problems associated with providing a memory module with sufficient storage capacity, data processing speed, and energy efficiency for effective operation in a data center, e.g., a data center that for processing AI and/or ML models. Some example benefits are discussed herein in connection with various features and functionalities provided by the computing system as described. It will be appreciated that benefits explicitly discussed in connection with one or more embodiments described herein are provided by way of example and are not intended to be an exhaustive list of all possible benefits of the computing system.

### Particular Implementations

Described implementations of the subject matter can include one or more features, alone or in combination, as described in the following clauses.

Clause 1. A memory module comprising:
a photonic integrated circuit (PIC);
an electric integrated circuit (EIC) stacked on the PIC and having a first memory interface and a second memory interface;
photonic transceivers optically coupled to the PIC and electrically coupled to the EIC;
first memory electrically coupled to the first memory interface of the EIC;
second memory electrically coupled to the second memory interface of the EIC;
the EIC including a cache manager between the first memory interface and the second memory interface, and a memory controller between the first memory and the photonic transceivers; and
wherein the PIC, EIC, photonic transceivers, first memory, and second memory are co-packaged.

Clause 2. The memory module of clause 1, wherein the first memory interface is a DDR PHY interface and the second memory interface is an HBM PHY interface.

Clause 3. The memory module of clause 1 or clause 2, wherein the first memory interface and the second memory interface are located proximate to a perimeter edge of the EIC and wherein the photonic transceivers are located in an interior region of the EIC.

Clause 4. The memory module of any of the clauses 1 to 3, wherein the second memory interface has a higher speed than the first memory interface.

Clause 5. The memory module of any of the clauses 1 to 4, wherein each photonic transceiver includes a first portion in the EIC, a second portion in the PIC, and electrical interconnects that electrically couple the first portion in the EIC and the second portion in the PIC.

Clause 6. The memory module of any of the clauses 1 to 5, wherein:
the first portion of each photonic transceiver in the EIC includes a driver and an amplifier; and
the second portion of each photonic transceiver in the PIC includes a modulator and a photodetector.

Clause 7. The memory module of any of the clauses 1 to 6, wherein:
the driver of each photonic transceiver includes a driver interface at a bottom major surface of the EIC;
the amplifier of each photonic transceiver includes an amplifier interface at the bottom major surface of the EIC;
the modulator of each photonic transceiver includes a modulator interface at a top major surface of the PIC;
the photodetector of each photonic transceiver includes a photodetector interface at the top major surface of the PIC;
wherein the driver interface is coupled to the modulator interface by a first electrical interconnect and the amplifier interface is coupled to the photodetector by a second electrical interconnect.

Clause 8. The memory module of any of the clauses 1 to 7, wherein the first portion of each photonic transceiver is vertically aligned with a second portion of a corresponding photonic transceiver.

Clause 9. The memory module of any of the clauses 1 to 8, wherein the second portion of each photonic transceiver in the PIC includes an electro-absorption modulator.

Clause 10. The memory module of any of the clauses 1 to 9, wherein:
each photonic transceiver includes a first portion in the EIC, a second portion in the PIC, and electrical interconnects that electrically couple the first portion in the EIC and the second portion in the PIC;
the first portion of each photonic transceiver in the EIC includes a driver and an amplifier; and
the second portion of each photonic transceiver in the PIC includes a modulator and a photodetector; and
wherein the first portion of each photonic transceiver is vertically aligned with a second portion of a corresponding photonic transceiver.

Clause 11. The memory module of any of the clauses 1 to 10, wherein the photonic transceivers are located in an interior region of the EIC.

Clause 12. The memory module of any of the clauses 1 to 11, wherein the cache manager is configured to modify the data that is transferred from the first memory to the second memory through the EIC.

Clause 13. The memory module of any of the clauses 1 to 12, wherein the cache manager is configured to request the data from the first memory via the first memory interface and to transfer the data to the second memory via the second memory interface.

Clause 14. The memory module of any of the clauses 1 to 13, wherein the EIC further includes a PCIe interface.

Clause 15. The switching system of any of the clauses 1 to 14, wherein the electrical interconnects are less than 200 microns.

Clause 16. The switching system of any of the clauses 1 to 15, wherein the PIC includes an optical port configured for connection to a light engine.

Clause 17. A memory module comprising:
a photonic integrated circuit (PIC);
an electric integrated circuit (EIC) stacked on the PIC and having a first memory interface and a second memory interface; and
photonic transceivers optically coupled to the PIC and electrically coupled to the EIC;
the EIC including a cache manager between the first memory interface and the second memory interface, and a memory controller between second memory interface and the photonic transceivers.

Clause 18. A memory module comprising:
a photonic integrated circuit (PIC);
an electric integrated circuit (EIC) stacked on the PIC and having a first memory interface and a second memory interface; and
photonic transceivers optically coupled to the PIC and electrically coupled to the EIC, the photonic transceivers at a first end of a bidirectional route for optical signals to travel to and from an external process at a second end of the bidirectional route;

wherein the EIC is configured to 1) obtain a datum from a first memory, via the first memory interface, 2) provide the datum to a second memory, via the second memory interface, 3) receive a request along the bidirectional route to read the datum from the external process, 4) transmit optical signals corresponding to the datum in the second memory into the PIC via at least one of the photonic transceivers along the bidirectional route to the external process in response to the request.

Clause 19. A method comprising:
transferring a datum from a first memory unit of a memory module to a cache manager of the memory module, wherein the memory module includes a photonic integrated circuit (PIC), an electrical integrated circuit (EIC) stacked on the PIC, and a photonic interface that is optically coupled to the PIC and electrically coupled to the EIC;
transferring the datum from the cache manager to a second memory unit of the memory module; and
transmitting signals corresponding to the datum in the second memory unit into the PIC via the photonic interface in response to a request received at a memory manager of the EIC via the photonic interface.

Clause 20. The method of clause 19, wherein the first memory unit comprises DDR memory and the second memory unit comprises HBM.

Clause 21. The method of clause 19 or clause 20, wherein transferring the datum from the cache manager to a second memory unit of the memory module includes taking a caching action of modifying the datum at the EIC.

Clause 22. An integrated circuit for a memory module comprising:
a first memory interface;
a second memory interface; and
a first portion of a photonic transceiver, the first portion of the photonic transceiver including a driver and a driver interface that is electrically coupled to the driver and exposed at a bottom major surface of the EIC and an amplifier and an amplifier interface that is electrically coupled to the amplifier and exposed at a bottom major surface of the EIC;
a cache manager between the first memory interface and the second memory interface; a memory controller between the first portion of the photonic transceiver and the second memory interface;
wherein the cache manager is configured to 1) obtain a datum from a first memory, via the first memory interface, and 2) provide the datum to a second memory, via the second memory interface; and
wherein the memory controller is configured to 1) receive a request via the first portion of the photonic interface to read or write to the first memory, and 2) transmit driver signals that correspond to the datum in the second memory to the driver interface of the first portion of the photonic transceiver in response to a request.

Clause 23. The integrated circuit of clause 22, wherein the first memory interface is a DDR PHY interface and the second memory interface is an HBM PHY interface.

Clause 24. The integrated circuit of clause 22 or clause 23, wherein the first memory interface and the second memory interface are located proximate to a perimeter edge of the EIC.

Clause 25. The integrated circuit of any of the clauses 22 to 24, wherein the second memory interface has a higher speed than the first memory interface.

Clause 26. The integrated circuit of claim 22 wherein:
the first memory interface is located proximate to a perimeter edge of the integrated circuit; the second memory interface is located proximate to a perimeter edge of the integrated circuit; and
the first portion of the photonic transceiver is located in an interior region of the integrated circuit.

Clause 27. The integrated circuit of clause 26, wherein the cache manager configured to modify the datum that is provided to the second memory.

Clause 28. The memory module of clause 26 or clause 27, wherein the integrated circuit further includes a PCIe interface.

Clause 29. A method comprising:
receiving a datum at a first memory interface of an EIC of a memory module, wherein the EIC includes a first portion of a photonic interface and a PIC of the memory module includes a second portion of the photonic interface;
transferring the datum from the EIC via a second memory interface; and
receiving the datum at the EIC via the second memory interface;
transmitting signals corresponding to the datum received at the second memory interface into the PIC of the memory module via the photonic interface in response to a request received at the EIC via the photonic interface.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

It should also be noted that at least some of the operations for the methods described herein may be implemented using software instructions stored on a computer useable storage medium for execution by a computer. As an example, an embodiment of a computer program product includes a computer useable storage medium to store a computer readable program.

The computer-useable or computer-readable storage medium can be an electronic, magnetic, optical, electromagnetic, infrared, or semiconductor system (or apparatus or device).

Examples of non-transitory computer-useable and computer-readable storage media include a semiconductor or solid state memory, magnetic tape, a removable computer diskette, a random access memory (RAM), a read-only memory (ROM), a rigid magnetic disk, and an optical disk.

Current examples of optical disks include a compact disk with read only memory (CD-ROM), a compact disk with read/write (CD-R/W), and a digital video disk (DVD).

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. An integrated circuit device for a memory module comprising:
a first memory interface;
a second memory interface; and
a first portion of a photonic transceiver, the first portion of the photonic transceiver including a driver and a driver interface that is electrically coupled to the driver and exposed at a bottom major surface of the integrated circuit device and an amplifier and an amplifier interface that is electrically coupled to the amplifier and exposed at a bottom major surface of the integrated circuit device;
a cache manager between the first memory interface and the second memory interface;
a memory controller between the first portion of the photonic transceiver and the second memory interface;
wherein the cache manager is configured to 1) obtain a datum from a first memory, via the first memory interface, and 2) provide the datum to a second memory, via the second memory interface; and
wherein the memory controller is configured to 1) receive a request via the first portion of the photonic interface to read or write to the first memory, and 2) transmit driver signals that correspond to the datum in the second memory to the driver interface of the first portion of the photonic transceiver in response to a request.

2. The integrated circuit device of claim 1, wherein the first memory interface is a DDR PHY interface and the second memory interface is an HBM PHY interface.

3. The integrated circuit device of claim 2, wherein the first memory interface and the second memory interface are located proximate to a perimeter edge of the integrated circuit device.

4. The integrated circuit device of claim 1, wherein the second memory interface has a higher speed than the first memory interface.

5. The integrated circuit device of claim 1, wherein:
the first memory interface is located proximate to a perimeter edge of the integrated circuit device;
the second memory interface is located proximate to a perimeter edge of the integrated circuit device; and
the first portion of the photonic transceiver is located in an interior region of the integrated circuit device.

6. The integrated circuit device of claim 5, wherein the first memory interface is a DDR PHY interface and the second memory interface is an HBM PHY interface.

7. The integrated circuit device of claim 1, wherein the cache manager configured to modify the datum that is provided to the second memory.

8. The integrated circuit device of claim 1, wherein the integrated circuit device further includes a PCIe interface.

9. The integrated circuit device of claim 1, wherein:
the first memory interface is located proximate to a perimeter edge of the integrated circuit device;
the second memory interface is located proximate to a perimeter edge of the integrated circuit device;
the first portion of the photonic transceiver is located in an interior region of the integrated circuit device;
the first memory interface is a DDR PHY interface and the second memory interface is an HBM PHY interface; and
the integrated circuit device further includes a PCIe interface.

10. An integrated circuit device for a memory module comprising:
a plurality of first memory interfaces;
a plurality of second memory interfaces; and
a plurality of first portions of photonic transceivers, the first portion of each photonic transceiver including a driver and a driver interface that is electrically coupled to the driver and exposed at a bottom major surface of the integrated circuit device and an amplifier and an amplifier interface that is electrically coupled to the amplifier and exposed at a bottom major surface of the integrated circuit device;
a cache manager between the plurality of first memory interfaces and the plurality of second memory interfaces;
a memory controller between the plurality of first portions of the photonic transceivers and the plurality of second memory interfaces;
wherein the cache manager is configured to 1) obtain a datum from a first memory, via the one of the first memory interfaces, and 2) provide the datum to a second memory, via one of the second memory interfaces; and
wherein the memory controller is configured to 1) receive a request via one of the first portions of the photonic interfaces to read or write to the first memory, and 2) transmit driver signals that correspond to the datum in the second memory to the driver interface of the one of the first portions of the photonic transceivers in response to a request.

11. The integrated circuit device of claim 10, wherein the plurality of first memory interfaces are DDR PHY interfaces and the plurality of second memory interfaces are HBM PHY interfaces.

12. The integrated circuit device of claim 11, wherein the plurality of first memory interfaces and the plurality of second memory interfaces are located proximate to a perimeter edge of the integrated circuit device and the plurality of first portions of the photonic transceivers are located in an interior region of the integrated circuit device.

13. A method comprising:
receiving a datum at a first memory interface of an electronic integrated circuit (EIC) of a memory module, wherein the EIC includes a first portion of a photonic interface and a photonic integrated circuit (PIC) of the memory module includes a second portion of the photonic interface;
transferring the datum from the EIC via a second memory interface; and
receiving the datum at the EIC via the second memory interface;
transmitting signals corresponding to the datum received at the second memory interface into the PIC of the memory module via the photonic interface in response to a request received at the EIC via the photonic interface.

14. The method of claim 13, wherein the first memory interface is configured for a first memory unit, which comprises DDR memory and the second memory interface is configured for a second memory unit, which comprises HBM.

15. The method of claim 13, wherein transferring the datum from the EIC via the second memory interface includes taking a caching action of modifying the datum at the EIC.

16. The method of claim 13, wherein:
the first memory interface is configured for a first memory unit, which comprises DDR memory and the second memory interface is configured for a second memory unit, which comprises HBM; and
transferring the datum from the EIC via the second memory interface includes taking a caching action of modifying the datum at the EIC.
